(19) United States
(12) Patent Application Publication
(10) Pub. No.: US 2008/0153307 A1
(43) Pub. Date: Jun. 26, 2008

(54) METHOD OF PRODUCING SEMICONDUCTOR DEVICE

(76) Inventors: Yuji Yamada, Yokohama-shi (JP); Hiroshi Tomita, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/952,254

(22) Filed: Dec. 7, 2007

(30) Foreign Application Priority Data
Dec. 11, 2006 (JP) P2006-333141

(51) Int. Cl. H01L 21/465

(52) U.S. Cl. 438/745; 257/E21.485

(57) ABSTRACT

A method of producing a semiconductor device that a semiconductor substrate having holes formed by a dry etching process is wet-etched and the residue resulting from the dry etching process is removed, comprising a chemical solution supply process of supplying a wet etching chemical solution to the front surface of the semiconductor substrate to charge the chemical solution into the holes, a surface chemical solution removing process of removing the chemical solution from the front surface of the semiconductor substrate with the chemical solution in the holes maintained, a wet etching process of performing wet etching of the interiors of the holes with the chemical solution kept removed from the front surface of the semiconductor substrate, and an in-hole chemical solution removing process of removing the chemical solution from the interiors of the holes.

### CROSS-REFERENCE TO RELATED APPLICATIONS

This application is based upon and claims the benefit of priority from the prior Japanese Patent Application No. 2006-333141, filed on Dec. 11, 2006; the entire contents of which are incorporated herein by reference.

### BACKGROUND OF THE INVENTION

1. Field of the Invention

The present invention relates to a method of producing a semiconductor device suitable for production of a semiconductor device having holes having a high aspect ratio.

2. Description of the Related Art

In a case where holes having a high aspect ratio, which are called contact holes, through holes and the like, are fabricated by dry etching in a semiconductor device production process, and especially a wiring process, the deposited material such as etching residue in the holes is conventionally removed by a process of washing and removing by wet etching using a chemical solution.

In the above-described process, as the chemical solution, an organic chemical solution and buffered hydrofluoric acid which can perform isotropic etching are used in order to prevent extreme reduction of a film that is exposed on the surface of the semiconductor substrate or a film that is exposed on inner walls of the contact holes. But, the progress of miniaturization and the provision of a high aspect ratio hole diameter have problems that an etching rate of the inner surfaces of the holes decreases to several percent in comparison with that of the film on a flat portion, and satisfactory etching cannot be performed.

For example, when an etching amount is calculated from the hole inside volume and the concentration of etching species, the etching amount becomes about 1% in comparison with the etching amount of the film of the flat portion when the hole diameter is 50 nm, and etching is limited to merely about one percent of a target etching amount. Meanwhile, in a case where the etching is performed such that the etching amount in such holes becomes a desired amount, another portion, e.g., a film exposed on the substrate surface, is excessively etched and decreased extremely.

There is known a method of preventing excessive etching by using a test pattern on a dummy substrate independent of a product substrate to measure a film thickness in processing by the chemical solution for removing dry etching residues (for example, JP-A 2000-223464). But, the above method requires a flat portion having a certain area to measure the film thickness on the dummy substrate, and there is apprehension that the dummy substrate and the dry etching residues of a real product are different in a residue amount to be removed and an etching rate of the chemical solution.

There is proposed a method of improving detergency by increasing a discharge pressure of a chemical solution or a rinse solution by means of a booster pump (for example, JP-A2003-168669). This method can be expected to provide an effect that the etching rate in the holes is set closer to that of the film of the flat portion by improving the displacement efficiency of the chemical solution in the holes, but a level of improvement of the etching rate in the holes has not been confirmed.

### SUMMARY OF THE INVENTION

The present invention provides a method of producing a semiconductor device that desired good wet etching processing can be performed and a good semiconductor device can be produced even when the semiconductor substrate has holes with a high aspect ratio.

According to an aspect of the present invention, there is provided a method of producing a semiconductor device that a semiconductor substrate having holes formed by a dry etching process is wet-etched and the residue resulting from the dry etching process is removed, comprising a chemical solution supply process of supplying a wet etching chemical solution to the front surface of the semiconductor substrate to charge the chemical solution into the holes, a surface chemical solution removing process of removing the chemical solution from the front surface of the semiconductor substrate with the chemical solution in the holes maintained, a wet etching process of performing wet etching of the interiors of the holes with the chemical solution kept removed from the front surface of the semiconductor substrate, and an in-hole chemical solution removing process of removing the chemical solution from the interiors of the holes.

### BRIEF DESCRIPTION OF THE DRAWINGS

FIG. 1 is a diagram schematically showing a sectional structure of a semiconductor substrate according to an embodiment of the invention.

FIG. 2 is a diagram schematically showing a structure of a semiconductor manufacturing apparatus according to the embodiment of the invention.

FIG. 3 is a flow chart showing steps according to the embodiment of the invention.

FIG. 4 is a graph showing a relation between an elapsed time and an etching amount according to Example 1.

FIG. 5 is a diagram schematically showing a sectional structure of a semiconductor substrate according to Example 2 of the invention.

FIG. 6 is a diagram schematically showing a sectional structure of a semiconductor substrate according to Example 3 of the invention.

FIGS. 7A to 7D are diagrams illustrating a production process of a semiconductor device applying an embodiment of the invention.

### DESCRIPTION OF THE EMBODIMENTS

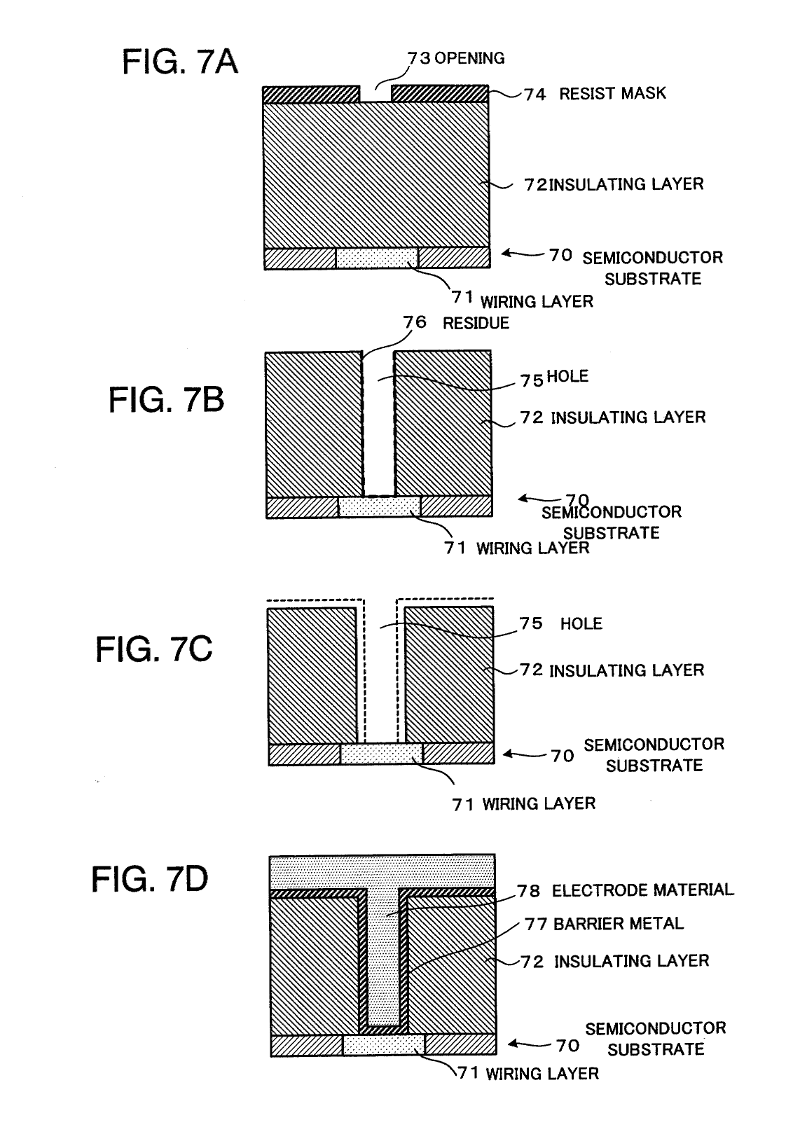

Embodiments of the present invention will be described with reference to the figures. First, a production process (wiring process) of a semiconductor device applying this embodiment is described with reference to FIGS. 7A to 7D. As shown in FIG. 7A, a wiring layer 71 is formed in a semiconductor substrate 70, and an insulating layer 72 formed of a silicon oxide film or the like is formed on the wiring layer 71. A resist mask 74 which has an opening 73 having a prescribed size is formed on the surface of the insulating layer 72 by photolithography using a photoresist.

As shown in FIG. 7B, a hole 75 is formed in the insulating layer 72 to reach the wiring layer 71 by dry etching using the resist mask 74, and the remaining resist mask 74 is removed by ashing or the like. In this state, etching residue 76 produced during the dry etching adheres to the interior of the hole 75, and the like.

As shown in FIG. 7C, the above-described etching residue 76 is removed by a wet etching process (washing process) described later. As indicated by dotted lines in the figure, the inner side wall of the hole 75 and the insulating layer 72 on the surface are slightly scraped by etching.

As shown in FIG. 7D, a barrier metal 77 and an electrode material 78 made of metal or polysilicon are buried into the hole 75, and wiring for electrically connecting the wiring layer 71 and the surface of the insulating layer 72 is formed. The embodiment of the invention according to the wet etching process from the state shown in FIG. 7B to the state shown in FIG. 7C will be described below.

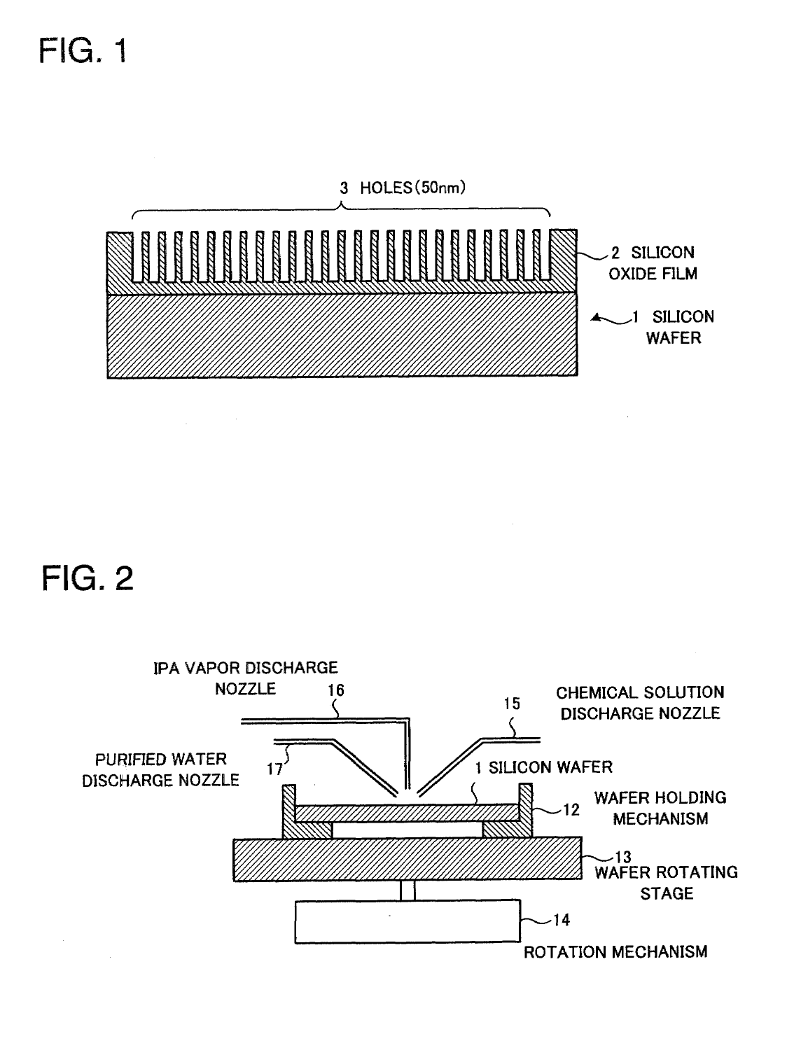

FIG. 1 is a sectional view schematically showing a structure of a semiconductor substrate according to the embodiment of the invention. As shown in the figure, a silicon oxide film 2 is formed on a silicon wafer 1 having a diameter of, for example, 300 mm, and lots of holes 3 are formed in the silicon oxide film 2 by lithography and dry etching.

FIG. 2 schematically shows a structure of a single wafer processing type semiconductor manufacturing apparatus used in the embodiment of the invention. The semiconductor manufacturing apparatus is provided with a wafer holding mechanism 12 for holding the silicon wafer 1, and the wafer holding mechanism 12 is provided on a wafer rotating stage 13. The wafer rotating stage 13 is connected to a rotation mechanism 14, so that the silicon wafer 1 in the held state can be rotated at a prescribed rotation speed. A chemical solution discharge nozzle 15, an IPA (isopropyl alcohol) vapor discharge nozzle 16 and a purified water discharge nozzle 17 are disposed above the wafer holding mechanism 12 to supply the front surface of the silicon wafer 1 with a chemical solution, IPA vapor and purified water.

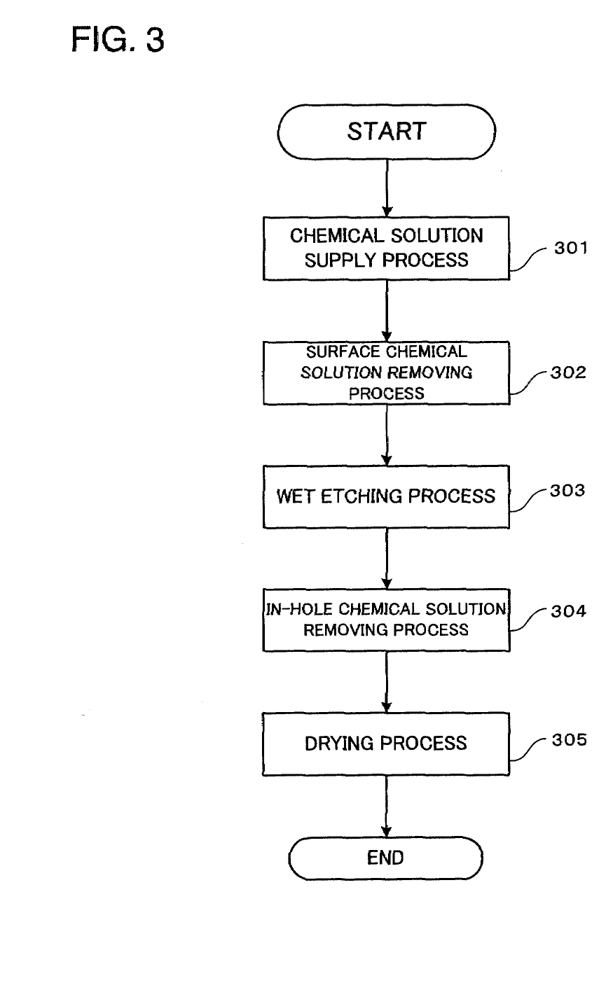

In this embodiment, the silicon wafer 1 shown in FIG. 1 is placed in the wafer holding mechanism 12 of the semiconductor manufacturing apparatus shown in FIG. 2. And, as shown in a flow chart of FIG. 3, a chemical solution supply process is performed to supply a prescribed chemical solution (e.g., buffered hydrofluoric acid or diluted hydrofluoric acid) to the surface of the silicon wafer 1 and into the holes 3 through the chemical solution discharge nozzle 15 (301).

Then, the IPA vapor is supplied to the surface of the silicon wafer 1 through the IPA vapor discharge nozzle 16, and a surface chemical solution removing process is performed to remove only the chemical solution on the surface of the silicon wafer 1 while keeping the chemical solution in the holes 3 of the silicon wafer 1 (302).

A wet etching process is then performed to perform wet etching in the holes 3 with the chemical solution is kept in the holes 3 while the chemical solution on the surface of the silicon wafer 1 kept removed (303).

Lastly, an in-hole chemical solution removing process is performed to remove the chemical solution from the holes 3 by supplying purified water to the surface of the silicon wafer 1 through the purified water discharge nozzle 17 and displacing the chemical solution with the purified water (304), and a drying process is performed to dry the silicon wafer 1 with IPA vapor or the like (305).

### Example 1

As Example 1, the silicon oxide film (SiO₂) 2 having a thickness of 600 nm was formed on the silicon wafer 1 having a diameter of 300 mm as shown in FIG. 1, and lots of holes 3 each having a hole diameter of 50 nm and a depth of 500 nm were formed in the silicon oxide film 2 by lithography and dry etching.

The silicon wafer 1 was set in the wafer holding mechanism 12 of a single wafer processing type semiconductor manufacturing apparatus shown in FIG. 2. The chemical solution supply process was performed by discharging a chemical solution A (including 3 mol/L of hydrofluoric acid, 8 mol/L of ammonium fluoride and 1000 ppm or less of a surfactant) to the center of the silicon wafer 1 through the chemical solution discharge nozzle 15 at a flow rate of 2 L/min while rotating the silicon wafer 1 at 1000 rpm for three seconds.

The IPA vapor discharge nozzle 16 was scanned from the center to the outer circumference of the silicon wafer 1 which was being rotated over 10 seconds while discharging the IPA vapor, which was produced from a heated IPA, onto the silicon wafer 1 through the IPA vapor discharge nozzle 16. Thus, the surface chemical solution removing process was performed to remove only the chemical solution A on the surface of the silicon wafer 1 while keeping the chemical solution A in the holes 3.

The wet etching process was performed while rotating the silicon wafer 1 for 30 seconds with the chemical solution A kept in the holes 3 and the chemical solution A removed from the surface of the silicon wafer 1.

Purified water was discharged to the center of the wafer 1 through the purified water discharge nozzle 17 at a flow rate of 2 L/min for 30 seconds, and the in-hole chemical solution removing process was performed to remove the chemical solution A from the holes 3 by displacing it with the purified water.

Lastly, the IPA vapor generated from the heated IPA was discharged again onto the wafer 1 through the IPA vapor discharge nozzle 16 to perform the drying process. At that time, the IPA vapor discharge nozzle 16 was scanned from the center to the outer circumference of the silicon wafer 1 over 30 seconds. In other words, the drying process was performed over a time period longer than that for the above-described surface chemical solution removing process in order to displace and dry the purified water in the holes 3 with the IPA.

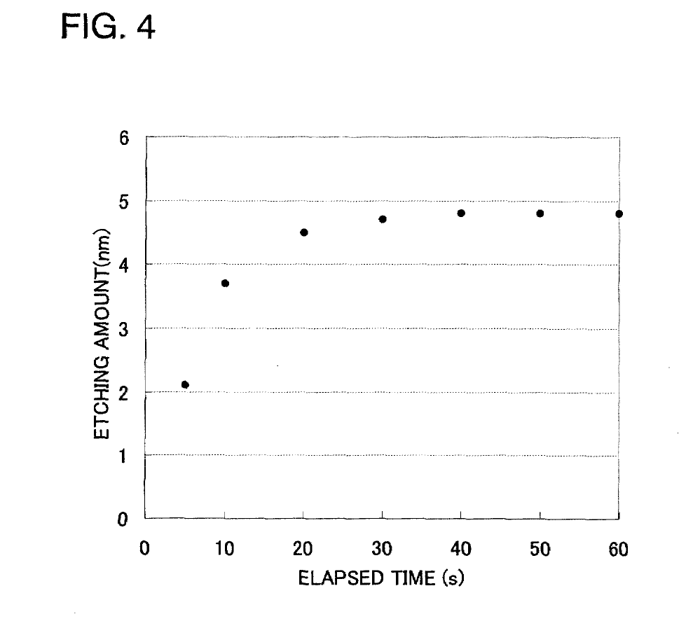

In the above Example 1, the chemical solution A is charged into the holes 3 of the silicon wafer 1, and the chemical solution A on the surface of the silicon wafer 1 is displaced with the IPA by the IPA vapor and removed from the surface of the silicon wafer 1. In this state, the surface of the silicon wafer 1 is not etched, but only the interiors of the holes 3 are etched. The chemical solution A in the holes 3 reacts with the silicon oxide film 2 on the inner walls of the holes 3 to cause etching. Etching species contained in the chemical solution A within the holes 3 is very small in amount and not supplemented from the outside, so that the concentration of the etching species is decreased and the etching rate is lowered along with the reaction with the silicon oxide film 2. The results obtained by checking the relation between the elapsed time and the etching amount at that time are indicated by the graph of FIG. 4. It is apparent from the graph that etching is substantially stopped in 30 seconds after the chemical solution A is supplied into the holes 3 in Example 1. The graph of FIG. 4 shows the results obtained by checking the etching amount of the inner walls of the holes 3 with a time period between the supply of the chemical solution A into the holes 3 and the displacement of it with the purified water and removal (rinsing) varied.

In Example 1, it took about 40 seconds or more to remove the chemical solution A from the holes 3 after supplying the chemical solution A into the holes 3 and displacing it with the purified water, and the etching in the holes 3 was completed in self-alignment.

A cross section of the silicon wafer 1 processed as described above was observed through a transmission electron microscope to find that the silicon oxide film 2 on the inner walls of the holes 3 was etched by 4.5 to 5 nm in comparison with the state prior to the processing. The silicon oxide film 2 was measured its thickness at a portion (surface portion) where the pattern was not formed to find that it was etched by 5 to 5.5 nm in comparison with the state prior to the processing. In other words, the surface of the silicon wafer 1 and the interiors of the holes 3 could be etched to a substantially same etching amount by the wet etching in Example 1.

In the above-described wet etching process, the silicon wafer 1 was rotated at 1000 rpm. But, since this process does not supply the chemical solution A to the silicon wafer 1, the rotation may be stopped.

In the above-described Example 1, the IPA vapor was used to remove the chemical solution A from the front surface of the silicon wafer 1 in the surface chemical solution removing process, but the IPA may be used in a liquid state. It is preferable to use IPA vapor because IPA vapor supplying method has been already established, and also IPA liquid is easy to introduce into existing manufacturing apparatus. As a method to remove the chemical solution A from the surface of the silicon wafer 1 in the surface chemical solution removing process, the following methods may be used.

Method of removing the chemical solution A from the front surface of the silicon wafer 1 by blowing gas (e.g., nitrogen gas or the like) other than the IPA vapor. This method is preferable for cost reduction with eliminating IPA consumption.

Method of controlling the rotation speed of the silicon wafer 1 to remove only the chemical solution on the front surface of the silicon wafer 1 due to action of centrifugal force produced by rotating it while keeping the chemical solution in the holes 3. This method is preferable for cost reduction, and also it is easy to introduce into existing manufacturing apparatus.

Method of displacing the chemical solution A on the front surface of the silicon wafer 1 with a solution (e.g., an organic solvent (ketones or the like) or a high viscosity liquid (concentrated phosphoric acid or the like)) which is hard to mix with the chemical solution A. This method is preferable to introduce into existing manufacturing apparatus easily.

Method of freezing the chemical solution A on the front surface of the silicon wafer 1 to remove it as solids (particles) and melting the chemical solution A remained in the holes 3.

As a method of freezing the chemical solution A, dry ice or liquid nitrogen may be poured on the front surface of the silicon wafer 1 or contacted to its back surface. This method is preferable for lower load against effluent treatment facilities.

Method of supplying concentrated sulfuric acid (having a dehydrating action, a large specific gravity and a high viscosity) to displace the chemical solution A with it on the front surface of the silicon wafer 1 or absorbing (dehydration reaction) the chemical solution A. This method is preferable to introduce into existing manufacturing apparatus easily.

In a case where it is possible to control the interiors of the holes 3 to have a hydrophilic property and the surface of the silicon wafer 1 to have a hydrophobic property, the present invention can also be practiced by using a batch type apparatus which vertically holds the silicon wafer 1 and immerses it in the chemical solution. Regardless of whichever apparatus is used, it is necessary to discharge the etching chemical solution onto the silicon wafer 1, which is dry and free from the adhesion of the solution such as purified water, or to immerse the silicon wafer 1 therein to supply the chemical solution into the holes 3.

As described in Example 1, the chemical solution is charged into the holes 3 in the surface of the silicon wafer 1, and the chemical solution on the front surface of the silicon wafer 1 is removed according to the embodiment. Therefore, the interiors of the holes 3 can be etched without excessively etching the front surface of the silicon wafer 1. Generally, the etching amount is controlled according to an etching time period. But, the etching amount can be controlled by adjusting the amount of the etching species contained in the chemical solution within the holes 3 according to this embodiment. Therefore, it is sufficient by setting a prescribed etching time period or more, and it is not necessary to accurately control the etching time. In Example 1, the chemical solution was held to etch the interiors of the holes 3 for 30 seconds, but the holding time can be shortened or extended depending on the kind and concentration of the chemical solution and the etching substance. Similarly, the holding time can be shortened or extended to improve the accuracy of a target etching amount and the processing ability. As a method of adjusting the amount of the etching species, the concentration of the chemical solution may be adjusted, and when the buffered hydrofluoric acid or the like is used, the amount of the etching species may be controlled by adjusting a mixing ratio of hydrofluoric acid and ammonium fluoride.

### Example 2

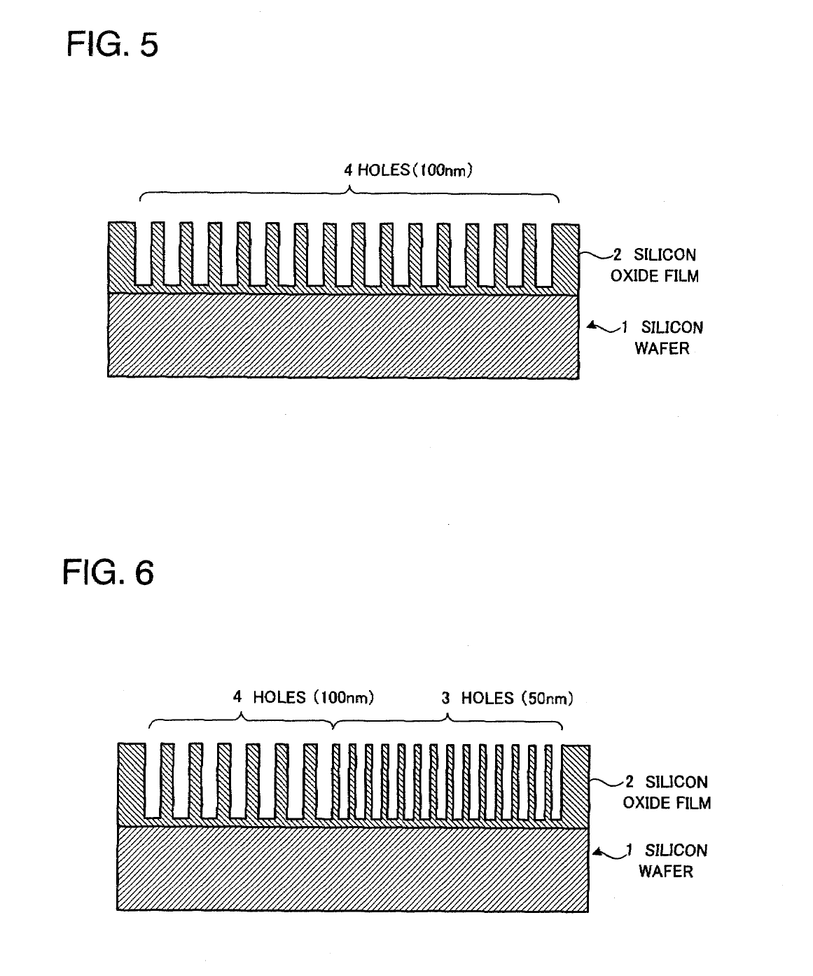

Example 2 is described below. In Example 2, the silicon oxide film (SiO₂) 2 having a thickness of 600 nm was formed on the silicon wafer 1 having a diameter of 300 mm as shown in FIG. 5, and lots of holes 4 each having a hole diameter of 100 nm and a depth of 500 nm were formed in the silicon oxide film 2 by lithography and dry etching.

The silicon wafer 1 was set in the wafer holding mechanism 12 of the single wafer processing type semiconductor manufacturing apparatus shown in FIG. 2. The chemical solution supply process was performed by discharging a chemical solution B (including 1.5 mol/L of hydrofluoric acid, 8 mol/L of ammonium fluoride and 1000 ppm or less of a surfactant) to the center of the silicon wafer 1 through the chemical solution discharge nozzle 15 at a flow rate of 2 L/min while rotating the silicon wafer 1 at 1000 rpm for six seconds.

Similar to Example 1, the surface chemical solution removing process, the wet etching process, the in-hole chemical solution removing process and the drying process were performed sequentially. A cross section of the silicon wafer 1 processed as described above was observed through a transmission electron microscope to find that the silicon oxide film 2 on the inner walls of the holes 4 was etched by 4.5 to 5 nm in comparison with the state prior to the processing. The silicon oxide film 2 was measured its thickness at a portion (surface portion) where the pattern was not formed to find that it was etched by 5 to 5.5 nm in comparison with the state prior to the processing. In other words, the surface of the silicon wafer 1 and the interiors of the holes 4 could be etched to a substantially same etching amount by the wet etching in Example 2.

In the above Example 2, the holes 4 had a diameter of 100 nm larger than in Example 1 where the holes 3 had a diameter of 50 nm, but good etching could be performed in the same manner as in Example 1 by adjusting the components of the chemical solution, the supply amount of the chemical solution and the like. The single layer silicon oxide film 2 was used in Example 1 and Example 2. But, in a case where plural layers having a different etching rate are stacked, a chemical solution complying with the etching rate of a film type to be etched is used.

### Example 3

Example 3 is described below. In Example 3, the silicon oxide film (SiO₂) 2 having a thickness of 600 nm was formed on the silicon wafer 1 having a diameter of 300 mm as shown in FIG. 6, and lots of holes 3 each having a hole diameter of 50 nm and a depth of 500 nm and lots of holes 4 each having a hole diameter of 100 nm and a depth of 500 nm were formed in the silicon oxide film 2 by lithography and dry etching.

The silicon wafer 1 was set in a wafer holding mechanism 12 of the single wafer processing type semiconductor manufacturing apparatus shown in FIG. 2. The chemical solution supply process was performed by discharging a chemical solution A (including 3 mol/L of hydrofluoric acid, 8 mil/L of ammonium fluoride and 1000 ppm or less of a surfactant) to the center of the silicon wafer 1 from the chemical solution discharge nozzle 15 at a flow rate of 2 L/min while rotating the silicon wafer 1 at 1000 rpm for three seconds.

Similar to Example 1, the surface chemical solution removing process, the wet etching process, the in-hole chemical solution removing process and the drying process were performed sequentially. A cross section of the silicon wafer 1 processed as described above was observed through a transmission electron microscope to find that the holes 3 having a hole diameter of 50 nm and a depth of 500 nm had the silicon oxide film 2, which was on the inner walls of the holes 3, etched by 4.5 to 5 nm in comparison with the state prior to the processing. Meanwhile, the holes 4 having a hole diameter of 100 nm and a depth of 500 nm had the silicon oxide film 2 on the inner walls of the holes etched by 9 to 10 nm in comparison with the state prior to the processing. The silicon oxide film 2 was measured its thickness at a portion (surface portion) where the pattern was not formed to find that it was etched by 5 to 5.5 nm in comparison with the state prior to the processing.

As described above, the etching amount of the holes 3 having a hole diameter of 50 nm in Example 3 could be made to have substantially the same thickness on the surface of the silicon wafer 1 and the interiors of the holes 3, but the etching amount for the holes 4 having a diameter of 100 nm was substantially doubled in comparison with the holes 3, and the hole diameter was increased as a result. Therefore, in such a case, the hole diameter is determined to be smaller by about 5 nm in the dry etching process which is preprocessing assuming that the size is variable when the holes 4 are formed, so that it is possible to conform the hole diameter after the wet etching to the desired size.

The invention is not limited to the embodiments and examples described above. It is to be understood that modifications and variations of the embodiments and examples can be made without departing from the spirit and scope of the invention.

What is claimed is:

1. A method of producing a semiconductor device that a semiconductor substrate having holes formed by a dry etching process is wet-etched and the residue resulting from the dry etching process is removed, comprising:
a chemical solution supply process of supplying a wet etching chemical solution to the front surface of the semiconductor substrate to charge the chemical solution into the holes;
a surface chemical solution removing process of removing the chemical solution from the front surface of the semiconductor substrate with the chemical solution in the holes maintained;
a wet etching process of performing wet etching of the interiors of the holes with the chemical solution kept removed from the front surface of the semiconductor substrate; and
an in-hole chemical solution removing process of removing the chemical solution from the interiors of the holes.

2. The method of producing a semiconductor device according to claim 1, further comprising a drying process of drying the semiconductor substrate after the in-hole chemical solution removing process.

3. The method of producing a semiconductor device according to claim 1, wherein an amount of an etching species in the chemical solution is adjusted to charge a prescribed amount of the etching species into the holes to perform wet etching of the interiors of the holes by a desired amount.

4. The method of producing a semiconductor device according to claim 1, wherein buffered hydrofluoric acid is used as the chemical solution.

5. The method of producing a semiconductor device according to claim 1, wherein diluted hydrofluoric acid is used as the chemical solution.

6. The method of producing a semiconductor device according to claim 1, wherein gas or liquid is supplied to the front surface of the semiconductor substrate in the surface chemical solution removing process to remove the chemical solution from the front surface of the semiconductor substrate.

7. The method of producing a semiconductor device according to claim 6, wherein the gas is IPA (isopropyl alcohol) vapor.

8. The method of producing a semiconductor device according to claim 1, wherein the semiconductor substrate is rotated in the surface chemical solution removing process.

9. The method of producing a semiconductor device according to claim 1, wherein purified water is used to remove the chemical solution from the holes in the in-hole chemical solution removing process.

10. The method of producing a semiconductor device according to claim 2, wherein the IPA (isopropyl alcohol) vapor is used to dry the semiconductor substrate in the drying process.

11. The method of producing a semiconductor device according to claim 1, wherein to form first holes having a first hole diameter and second holes having a second hole diameter larger than the first hole diameter in the semiconductor substrate, the second holes are formed to have a diameter smaller than the second hole diameter in the dry etching process, and the second holes are determined to have the second hole diameter by the wet etching process.

12. The method of producing a semiconductor device according to claim 1, wherein the holes are used for wiring by burying metal or polysilicon.
